(19) United States
(12) Patent Application Publication
(10) Pub. No.: US 2012/0266943 A1
(43) Pub. Date: Oct. 25, 2012

(54) SOLAR CELL MODULE STRUCTURE AND FABRICATION METHOD FOR PREVENTING POLARIZATION

(76) Inventor: Bo LI, San Jose, CA (US)

(21) Appl. No.: 13/090,847

(22) Filed: Apr. 20, 2011

(51) Int. Cl. H01L 31/048; H01L 31/0203

(52) U.S. Cl. 136/251; 438/66; 257/E31.117

(57) ABSTRACT

A solar cell module includes solar cells encapsulated in a high resistivity encapsulant. A protective package is created by forming together the high resistivity encapsulant, the solar cells, a transparent top cover and a backsheet. The protective package is mounted on a frame that is electrically isolated from the solar cells. The protective package may be created by lamination. The transparent top cover may comprise glass or a high resistivity material.

### TECHNICAL FIELD

The present invention relates generally to solar cells, and more particularly but not exclusively to solar cell modules.

### BACKGROUND

Solar cells are well known devices for converting solar radiation to electrical energy. They may be fabricated on a semiconductor wafer using semiconductor processing technology. A solar cell includes P-type and N-type diffusion regions. Solar radiation impinging on the solar cell creates electrons and holes that migrate to the diffusion regions, thereby creating voltage differentials between the diffusion regions. In a back junction solar cell, both the diffusion regions and the metal contact fingers coupled to them are on the backside of the solar cell. The metal contact fingers allow an external electrical circuit to be coupled to and be powered by the solar cell.

Several solar cells may be connected together to form a solar cell array. The solar cell array may be packaged into a solar cell module, which includes protection layers to allow the solar cell array to withstand environmental conditions and be used in the field. If precautions are not taken, solar cells may become highly polarized in the field, causing reduced output power. Solutions to solar cell polarization are disclosed in U.S. Pat. No. 7,554,031, which is incorporated herein by reference in its entirety.

### BRIEF SUMMARY

In one embodiment, a method of fabricating a solar cell module comprises placing a first sheet of encapsulant on front sides of a plurality of solar cells, placing a second sheet of encapsulant on backsides of the plurality of solar cells, and encapsulating the plurality of solar cells in a high resistivity encapsulant by heating together the first and second sheets encapsulant. The first sheet of encapsulant comprises an encapsulant having a volumetric resistance that is equal to or greater than 10¹⁶ Ωcm.

In another embodiment, a solar cell module comprises a plurality of solar cells encapsulated in a high resistivity encapsulant having a volume specific resistance equal to or greater than 10¹⁶ Ωcm over a normal operating temperature range of 45 to 85° C., a transparent top cover on front sides of the plurality of solar cells, a backsheet on backsides of the plurality of solar cells, and a frame framing the plurality of solar cells, the high resistivity encapsulant, the transparent top cover, and the backsheet. The high resistivity encapsulant is configured to prevent polarization by preventing charge from leaking from the front sides of the plurality of solar cells. The solar cells are electrically isolated from the frame.

In another embodiment, a solar cell module comprises a plurality of solar cells encapsulated in an encapsulant and a high resistivity transparent top cover having a volume specific resistance equal to or greater than 10¹⁶ Ωcm over a normal operating temperature range of 45 to 85° C. The solar cell module further comprises a backsheet and a frame framing the plurality of solar cells, the encapsulant, the high resistivity transparent top cover, and the backsheet. The high resistivity transparent top cover is configured to prevent polarization by preventing charge from leaking from the front sides of the plurality of solar cells. The solar cells are electrically isolated from the frame.

In another embodiment, a method of fabricating a solar cell module comprises placing a high resistivity transparent top cover on front sides of a plurality of solar cells, placing a first sheet of encapsulant under the high resistivity transparent top cover on the front sides of the plurality of solar cells, placing a second sheet of encapsulant on backsides of the plurality of solar cells, placing a backsheet under the second sheet of encapsulant on the backsides of the plurality of solar cells, and pressing and heating together the high resistivity transparent top cover, the first sheet of encapsulant, the plurality of solar cells, the second sheet of encapsulant, and the backsheet to create a protective package. The high resistivity transparent top cover has a volumetric resistance that is equal to or greater than 10¹⁶ Ωcm over a normal operating temperature range of 45 to 85° C.

These and other features of the present invention will be readily apparent to persons of ordinary skill in the art upon reading the entirety of this disclosure, which includes the accompanying drawings and claims.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures. The figures are not drawn to scale.

FIG. 1 shows a solar cell module in accordance with an embodiment of the present invention.

FIGS. 2-4 are cross-sectional views schematically illustrating fabrication of a solar cell module in accordance with an embodiment of the present invention.

FIGS. 5-7 are cross-sectional views schematically illustrating fabrication of a solar cell module in accordance with another embodiment of the present invention.

### DETAILED DESCRIPTION

In the present disclosure, numerous specific details are provided, such as examples of apparatus, components, and methods, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

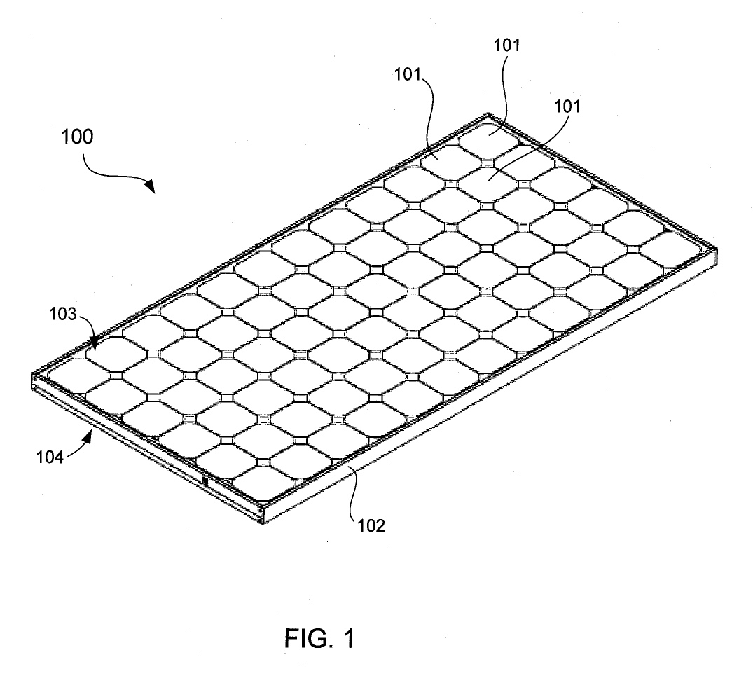

FIG. 1 shows a solar cell module 100 in accordance with an embodiment of the present invention. The solar cell module 100 is a so-called “terrestrial solar cell module” in that it is designed for use in stationary applications, such as on rooftops or by power generating stations. In the example of FIG. 1, the solar cell module 100 includes an array of interconnected solar cells 101. Only some of the solar cells 101 are labeled in FIG. 1 for clarity of illustration. The solar cells 101 may comprise back junction solar cells, which may experience polarization. Visible in FIG. 1 are the front sides of the solar cells 101, which face the sun during normal operation. The backsides of the solar cells 101 are opposite the front sides. A frame 102 provides mechanical support for the solar cell array.

The front portion of the solar cell module 100, which is labeled as 103, is on the same side as the front sides of the solar cells 101 and is visible in FIG. 1. The back portion 104 of the solar cell module 100 is under the front portion 103. As will be more apparent below, the front portion 103 includes layers of optically transparent protective and encapsulant materials that are formed over the front sides of the solar cells 101.

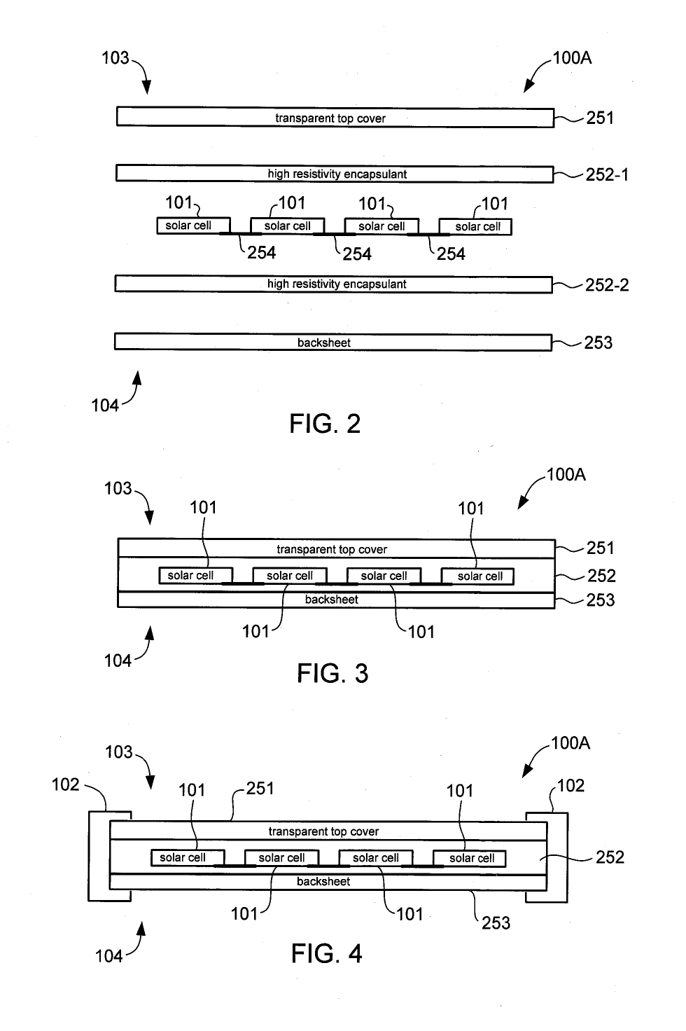

FIGS. 2-4 are cross-sectional views schematically illustrating fabrication of a solar cell module 100A in accordance with an embodiment of the present invention. The solar cell module 100A is a particular embodiment of the solar cell module 100 of FIG. 1.

FIG. 2 is an exploded view showing the components of the solar cell module 100A in accordance with an embodiment of the present invention. The solar cell module 100A may comprise a transparent top cover 251, a sheet of a high resistivity encapsulant 252-1, another sheet of a high resistivity encapsulant 252-2, the solar cells 101, interconnects 254, and a backsheet 253.

The transparent top cover 251 and the high resistivity encapsulant 252 (i.e., 252-1, 252-2) comprise optically transparent materials. The transparent top cover 251, which is the topmost layer on the front portion 103, protects the solar cells 101 from the environment. The solar cell module 100A is installed in the field such that the transparent top cover 251 faces the sun during normal operation. The front sides of the solar cells 101 face towards the sun by way of the transparent top cover 101. In the example of FIG. 2, the transparent top cover 201 comprises glass (e.g., 3.2 mm thick, soda lime glass).

The high resistivity encapsulant 252 comprises a high resistivity material configured to prevent solar cell polarization by preventing electrical charge from leaking from the front sides of the solar cells 101 to other portions of the solar cell module 100A. In one embodiment, the high resistivity encapsulant 252 presents a high resistance path to electrical charges to prevent charge leakage from the front sides of the solar cells 101 to the frame 102 or other portions of the solar cell module 100A by way of the transparent top cover 251. To be effective in preventing polarization, the high resistivity encapsulant 252 preferably has a volume specific resistance equal to or greater than 10¹⁶ (e.g., 10¹⁶-10¹⁹) Ωcm over a normal operating temperature range of 45 to 85° C. As a particular example, the high resistivity encapsulant 252 may comprise polyethylene or polyolefin having a volume specific resistance equal to or greater than 10¹⁶ Ωcm over a normal operating temperature range of 45 to 85° C. In addition to preventing solar cell polarization, the high resistivity encapsulant 252 also reduces leakage current and allows the solar cell module 100A to be employed in high voltage applications.

In the example of FIG. 2, sheets of high resistivity encapsulant 252 are placed on the front sides and backsides of the solar cells 101. In some embodiments, a sheet of high resistivity encapsulant 252 is only on the front sides of the solar cells 101. In those embodiments, the sheet of encapsulant on the backsides of the solar cells 101 is not a high resistivity encapsulant, such as poly-ethyl-vinyl acetate (“EVA”), for example.

The interconnects 254 may comprise a metal for electrically interconnecting the solar cells 101. In one embodiment, the solar cells 101 comprise serially-connected back junction solar cells. The interconnects 254 electrically connect to corresponding P-type and N-type diffusion regions on the backsides of the solar cells 101.

The backsides of the solar cells 101 face the backsheet 253. In one embodiment, the backsheet 253 comprises Tedlar/Polyester/EVA (“TPE”). The backsheet 253 may also comprise Tedlar/Polyester/Tedlar (“TPT”) or a multi-layer backsheet comprising a fluoropolymer, to name some examples. The backsheet 253 is on the back portion 104.

In one embodiment, the transparent top cover 251, the high resistivity encapsulant 252-1, the solar cells 101 electrically connected by the interconnects 254, the high resistivity encapsulant 252-2, and the backsheet 253 are formed together to create a protective package. This is shown in FIG. 3, where the aforementioned components are formed together in a stacking order as shown in FIG. 2. More particularly, the solar cells 101 are placed between the high resistivity encapsulants 252-1 and 252-2. The backsheet 253 is placed under the high resistivity encapsulant 252-2, and the transparent top cover 251 is placed over the high resistivity encapsulant 252-1. The just mentioned components are then pressed and heated together by vacuum lamination, for example. The lamination process melts together the sheet of high resistivity encapsulant 252-1 and the sheet of high resistivity encapsulant 252-2 to encapsulate the solar cells 101. In FIG. 3, the high resistivity encapsulant 252-1 and the high resistivity encapsulant 252-2 are labeled as “252” to indicate that that they have been melted together.

FIG. 4 shows the protective package of FIG. 3 mounted on the frame 102. Being encapsulated in the high resistivity encapsulant 252, the solar cells 101 are electrically isolated from the frame 102. The electrical isolation prevents electrical charge from leaking from the front sides of the solar cells 101 to the frame 102, thereby preventing polarization.

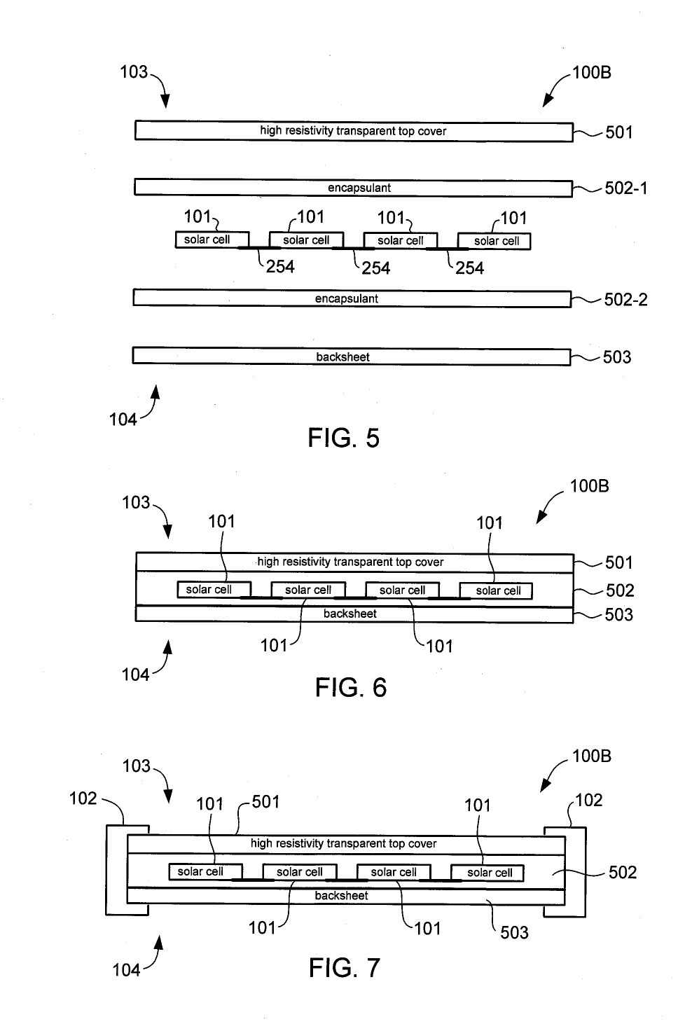

FIGS. 5-7 are cross-sectional views schematically illustrating fabrication of a solar cell module 100B in accordance with another embodiment of the present invention. The solar cell module 100B is a particular embodiment of the solar cell module 100 of FIG. 1.

FIG. 5 is an exploded view showing the components of the solar cell module 100B in accordance with an embodiment of the present invention. The solar cell module 100B may comprise a high resistivity transparent top cover 501, a sheet of encapsulant 502-1, another sheet of encapsulant 502-2, the solar cells 101, interconnects 254, and a backsheet 503.

The high resistivity transparent top cover 501 and the encapsulant 502 (i.e., 502-1, 502-2) comprise optically transparent materials. The high resistivity transparent top cover 501, which is the topmost layer on the front portion 103, protects the solar cells 101 from the environment. The solar cell module 100B is installed in the field such that the high resistivity transparent top cover 501 faces the sun during normal operation. The front sides of the solar cells 101 face towards the sun by way of the high resistivity transparent top cover 501.

The high resistivity transparent top cover 501 may comprise a high resistivity material configured to prevent solar cell polarization by preventing electrical charge from leaking from the front sides of the solar cells 101 to other portions of the solar cell module 100B. In one embodiment, the high resistivity transparent top cover 501 presents a high resistance path to electrical charges to prevent charge leakage from the front sides of the solar cells 101 to the frame 102 or other portions of the solar cell module 100B. To be effective in preventing polarization, the transparent top cover 501 preferably has a volume specific resistance equal to or greater than 10¹⁶ (e.g., 10¹⁶-10¹⁹) Ωcm over a normal operating temperature range of 45 to 85° C.

In one embodiment, the sheets of encapsulant 502 comprise an encapsulant material, such as poly-ethyl-vinyl acetate (“EVA”). In other embodiments, the sheets of encapsulant 502 comprise a high resistivity encapsulant as in the previously described solar cell module 100A (see FIG. 2).

The solar cell module 100B includes the solar cells 101 that are electrically connected on the backsides by the interconnects 254. The backsides of the solar cells 101 face the backsheet 503. In one embodiment, the backsheet 503 comprises Tedlar/Polyester/EVA (“TPE”). The backsheet 503 may also comprise Tedlar/Polyester/Tedlar (“TPT”) or a multi-layer backsheet comprising a fluoropolymer, to name some examples. The backsheet 503 is on the back portion 104.

In one embodiment, the high resistivity transparent top cover 501, the encapsulant 502-1, the solar cells 101 electrically connected by the interconnects 254, the encapsulant 502-2, and the backsheet 503 are formed together to create a protective package. This is shown in FIG. 6, where the aforementioned components are formed together in a stacking order as shown in FIG. 5. More particularly, the solar cells 101 are placed between the encapsulants 502-1 and 502-2. The backsheet 503 is placed under the encapsulant 502-2, and the high resistivity transparent top cover 501 is placed over the encapsulant 502-1. The just mentioned components are then pressed and heated together by vacuum lamination, for example. The lamination process melts together the sheet of encapsulant 502-1 and the sheet of encapsulant 502-2 to encapsulate the solar cells 101. In FIG. 6, the encapsulant 502-1 and the encapsulant 502-2 are labeled together as “502” to indicate that they have been melted together.

FIG. 7 shows the protective package of FIG. 6 mounted on the frame 102. Being encapsulated in the high resistivity encapsulant 502, the solar cells 101 are electrically isolated from the frame 102. The electrical isolation prevents electrical charge from leaking from the front sides of the solar cells 101 to the frame 102, thereby preventing polarization.

Solar cell module structures and fabrication methods for preventing polarization have been disclosed. While specific embodiments of the present invention have been provided, it is to be understood that these embodiments are for illustration purposes and not limiting. Many additional embodiments will be apparent to persons of ordinary skill in the art reading this disclosure.

1. A method of fabricating a solar cell module, the method comprising:
placing a first sheet of encapsulant on front sides of a plurality of solar cells, the first sheet of encapsulant having a volumetric resistance that is equal to or greater than 10¹⁶ Ωcm;
placing a second sheet of encapsulant on backsides of the plurality of solar cells; and
encapsulating the plurality of solar cells in a high resistivity encapsulant by heating together the first sheet of encapsulant and the second sheet of encapsulant.

2. The method of claim 1 wherein encapsulating the plurality of solar cells in the high resistivity encapsulant comprises:
pressing and heating a transparent top cover, the first sheet of encapsulant, the plurality of solar cells, the second sheet of encapsulant, and a backsheet together in a lamination process to form a protective package.

3. The method of claim 2 wherein the lamination process comprises vacuum lamination.

4. The method of claim 2 wherein the transparent top cover comprises glass.

5. The method of claim 2 further comprising:
mounting the protective package on a frame that is electrically isolated from the plurality of solar cells.

6. The method of claim 1 wherein the plurality of solar cells comprises serially-connected back junction solar cells.

7. The method of claim 1 wherein the first sheet of encapsulant comprises polyolefin having a volume specific resistance equal to or greater than 10¹⁶ Ωcm over a normal operating temperature range of 45 to 85° C.

8. The method of claim 1 wherein the first sheet of encapsulant comprises polyethylene having a volume specific resistance equal to or greater than 10¹⁶ Ωcm over a normal operating temperature range of 45 to 85° C.

9. The method of claim 1 wherein the first sheet of encapsulant has the volumetric resistance that is equal to or greater than 10¹⁶ Ωcm over a normal operating temperature range of 45 to 85° C.

10. A solar cell module comprising:
a plurality of solar cells encapsulated in a high resistivity encapsulant, the high resistivity encapsulant having a volume specific resistance equal to or greater than 10¹⁶ Ωcm over a normal operating temperature range of 45 to 85° C., the high resistivity encapsulant being configured to prevent polarization by preventing charge from leaking from front sides of the plurality of solar cells;
a transparent top cover over the plurality of solar cells;
a backsheet under the plurality of solar cells; and
a frame framing the plurality of solar cells, the high resistivity encapsulant, the transparent top cover, and the backsheet, the solar cells being electrically isolated from the frame.

11. The solar cell module of claim 10 wherein the transparent top cover comprises glass.

12. The solar cell module of claim 10 wherein the plurality of solar cells comprises back junction solar cells.

13. The solar cell module of claim 10 wherein the high resistivity encapsulant comprises polyolefin having a volume specific resistance equal to or greater than 10¹⁶ Ωcm over a normal operating temperature range of 45 to 85° C.

14. The solar cell module of claim 10 wherein the high resistivity encapsulant comprises polyethylene having a volume specific resistance equal to or greater than 10¹⁶ Ωcm over a normal operating temperature range of 45 to 85° C.

15. A solar cell module comprising:
a plurality of solar cells encapsulated in an encapsulant;
a high resistivity transparent top cover on front sides of the plurality of solar cells, the high resistivity transparent top cover having a volume specific resistance equal to or greater than 10¹⁶ Ωcm over a normal operating temperature range of 45 to 85° C., the high resistivity transparent top cover being configured to prevent polarization by preventing charge from leaking from the front sides of the plurality of solar cells;
a backsheet under the plurality of solar cells; and
a frame framing the plurality of solar cells, the encapsulant, the high resistivity transparent top cover, and the backsheet, the solar cells being electrically isolated from the frame.

16. The solar cell module of claim 15 wherein the plurality of solar cells comprises back junction solar cells.

17. The solar cell module of claim 15 wherein the encapsulant has a volume specific resistance equal to or greater than 10¹⁶ Ωcm over a normal operating temperature range of 45 to 85° C.

18-25. (canceled)
